(19) United States
(12) Patent Application Publication
(10) Pub. No.: US 2026/0251923 A1
(43) Pub. Date: Aug. 27, 2026

(54) Optical Modulator and Optical Transmitter

(71) Applicant: Nippon Telegraph and Telephone Corporation, Tokyo (JP)

(72) Inventors: Meishin Chin, Musashino-shi, Tokyo (JP); Takahiko Shindo, Musashino-shi, Tokyo (JP); Shigeru Kanazawa, Musashino-shi, Tokyo (JP)

(21) Appl. No.: 18/870,130

(22) PCT Filed: May 31, 2022
(86) PCT No.: PCT/JP2022/022156

§ 371 Date: Nov. 27, 2024

(51) Int. Cl. G02F 1/015; H01S 5/026; H01S 5/12

(52) U.S. Cl. CPC G02F 1/0157; H01S 5/0265; H01S 5/12

(57) ABSTRACT

Provided is an EA modulator and an EA-DFB laser having a structure for suppressing occurrence of stepping in mounting the EA modulator including a low dielectric constant material between a signal electrode pad and a GND electrode pad. The EA modulator according to the present disclosure is an electro-absorption optical modulator in which a low dielectric constant material is disposed between a signal electrode pad and a GND electrode pad, and the low dielectric constant material includes a notch recessed inward in a direction orthogonal to an optical axis direction.

### TECHNICAL FIELD

The present disclosure relates to an optical modulator and an optical transmitter, and more specifically, to an EA modulator and an EA-DFB laser equipped with the EA modulator.

### BACKGROUND ART

A distributed feedback laser (hereinafter, referred to as a DFB laser) has a narrow oscillation linewidth controlled by a diffraction grating. An EA-DFB laser in which the DFB laser and an external electro-absorption modulator (hereinafter, referred to as an EA modulator) are integrated generates high-speed signal light, and thus attracts attention as a device of an optical transmitter suitable for optical communication.

In recent years, there has been a demand for an increase in transmission capacity due to an increase in communication traffic, and there has been a demand for an optical transmitter to further increase a modulation rate. Since the EA-DFB laser has a high modulation rate of intensity modulation and a small change in refractive index during modulation, the EA-DFB laser is promising as a device for an optical transmitter that achieves such high-speed modulation. In addition, in recent years, extension of a transmission distance has been also required for cost reduction of communication infrastructure facilities, but since the EA-DFB laser has a feature of having a small chirp (fluctuation), it is expected as an optical transmitter for medium to long distance transmission. Furthermore, in the semiconductor laser, there is a problem that the output power may decrease as the temperature of the active layer rises, but the EA-DFB laser can also obtain high output power if having an embedded waveguide structure with high exhaust heat efficiency. As described above, the EA-DFB laser has attracted attention as a promising device for an optical transmitter that meets the needs of optical communication in recent years, such as medium to long distance transmission, high speed, and high output.

FIG. 1 is a diagram conceptually illustrating a structure of an EA modulator 10 according to a conventional technology, in which (a) illustrates a top view and (b) illustrates a cross-sectional view taken along a line Ib-Ib. In the EA-DFB laser, as illustrated in FIG. 1, the EA modulator 10 that performs intensity modulation of signal light includes: an EA absorption layer 11 that performs intensity modulation by controlling absorption of signal light; a p-type semiconductor 12 that is installed on an upper surface of the EA absorption layer in a z direction; an n-type semiconductor 13 that is installed on a lower surface of the EA absorption layer in the z direction; insulating layers 15a, b that are installed on both sides of a mesa region 14 that is a waveguide of signal light in a y direction; a GND electrode pad 16 that is installed on a lower surface of the n-type semiconductor 13 in the z direction and functions as an electrode; a signal electrode pad 17 that is installed on upper surfaces of the p-type semiconductor 12 and the insulating layer 15 in the z direction and functions as an electrode; and a bonding wire 18 for electrically connecting the signal electrode pad 17 and another device. Then, a periodic voltage that is repeatedly turned on and off is applied from a high frequency power supply 19 across the GND electrode pad 16 and the signal electrode pad 17, and the intensity of the signal light is modulated by controlling the absorption wavelength of the signal light according to the on and off of the voltage.

For example, indium phosphorus (InP) can be applied to the base materials of the p-type semiconductor 12, the n-type semiconductor 13, and the insulating layers 15a, b.

For example, InGaAsP or InGaAlAs having a multi quantum well (hereinafter, referred to as MQW) structure can be applied to the EA absorption layer 11. In this case, when a voltage is applied across the GND electrode pad 16 and the signal electrode pad 17, a reverse bias is applied to the EA absorption layer 11. As a result, the absorption wavelength determined by the band gap is shifted by the quantum confined Stark effect, and the absorption amount of the signal light can be efficiently controlled.

In the EA absorption layer 11 having such an MQW structure, it is known that the response speed of the control of the signal light is determined by the CR time constant in the EA absorption layer 11, and a capacitance C thereof includes two components of a component due to the EA absorption layer 11 and a component due to between the electrodes (the GND electrode pad 16 and the signal electrode pad 17). An attempt to improve the response speed by reducing the capacitance due to between the electrodes is already known.

In general, since the signal electrode pad 17 is connected to the bonding wire 18, it is necessary to secure a certain area, and capacitance as a capacitor is generated between the GND electrode pad 16 and the signal electrode pad 17. In order to reduce the capacitance, as illustrated in FIG. 2, a low dielectric constant material 21 is disposed between the GND electrode pad 16 and the signal electrode pad 17. Here, insulating layers 15c, d are arranged on both sides of the low dielectric constant material 21 in the y direction. In an EA modulator 20 having such a configuration, the capacitance between the GND electrode pad 16 and the signal electrode pad 17 is reduced as compared with the EA modulator 10, and the response speed of the signal light absorption amount control is improved. Benzocyclobutene (hereinafter, referred to as BCB) can be applied to the low dielectric constant material 21.

However, the EA modulator 20 including such a low dielectric constant material 21 has a problem of low yield in the mounting process.

FIG. 3 is a flowchart illustrating a mounting process 30 of an EA modulator including a low dielectric constant material below a signal electrode pad according to the conventional technology. The mounting process 30 an EA modulator comprising a low dielectric constant material below a signal electrode pad includes: forming a waveguide core including an EA absorption layer having an MOW structure on a substrate of an n-type semiconductor (step 31); forming a p-type semiconductor on an upper surface of the waveguide core (step 32); leaving a portion to be a mesa region and removing the other p-type semiconductor, waveguide core, and n-type semiconductor (step 33); embedding the removed region with an insulating material to form an insulating layer (step 34); forming a z-direction groove in a portion of the insulating layer to a depth reaching the n-type semiconductor (step 35); embedding the formed groove with a low dielectric constant material (step 36); and forming a GND electrode pad and a signal electrode pad (step 37).

In such a mounting process 30, for example, as illustrated in FIG. 4, it is assumed that a step in the height direction (z direction) is generated between the low dielectric constant material 21 and the insulating layer 15b, and the level of the EA modulator 20 in the xy plane cannot be secured and inclination occurs. Then, when the signal electrode pad 17 is formed by vapor deposition in step 37, a gap (stepping) may be generated in the end surface on the side in contact with the insulating layer 15c in the signal electrode pad 17 formed on the upper surface of the low dielectric constant material 21. This is because, due to the step and inclination described above, the end surface becomes a “shadow” of the insulating layer 15c, and incidence of flying particles serving as a base of the signal electrode pad 17 is prevented in vapor deposition.

In FIG. 4, the step in the z direction is drawn so as to be convex in the insulating layer 15c, but conversely, even when the low dielectric constant material 21 is convex, stepping may occur similarly. In this case, the stepping occurs in the signal electrode pad 17 formed on the upper surface of the insulating layer 15c.

As described above, in the conventional EA modulator including a low dielectric constant material, there is a problem that stepping occurs in the formation of the signal electrode pad, and the yield decreases accordingly.

### CITATION LIST

### Non Patent Literature

Non Patent Literature 1: T. Shindo et al., “25-Gbit/s 100-km Transmission 1358-nm-wavelength SOA Assisted Extended Reach EADFB Laser (AXEL) for 25 Gbit/s-class PON”, 2021 Optical Fiber Communications Conference and Exhibition (OFC), pp. 1-3 (2021)

### SUMMARY OF INVENTION

The present disclosure has been made in view of the above problems, and an object of the present disclosure is to provide an EA modulator and an EA-DFB laser having a structure for suppressing occurrence of stepping in mounting of the EA modulator including a low dielectric constant material between a signal electrode pad and a GND electrode pad.

In order to solve the above problem, the present disclosure provides an electro-absorption optical modulator in which a low dielectric constant material is disposed between a signal electrode pad and a GND electrode pad, the low dielectric constant material including a notch recessed inward in a direction orthogonal to an optical axis direction.

### BRIEF DESCRIPTION OF DRAWINGS

FIG. 1 is a diagram conceptually illustrating a structure of an EA modulator 10 according to a conventional technology, in which (a) illustrates a top view and (b) illustrates a cross-sectional view taken along a line Ib-Ib.

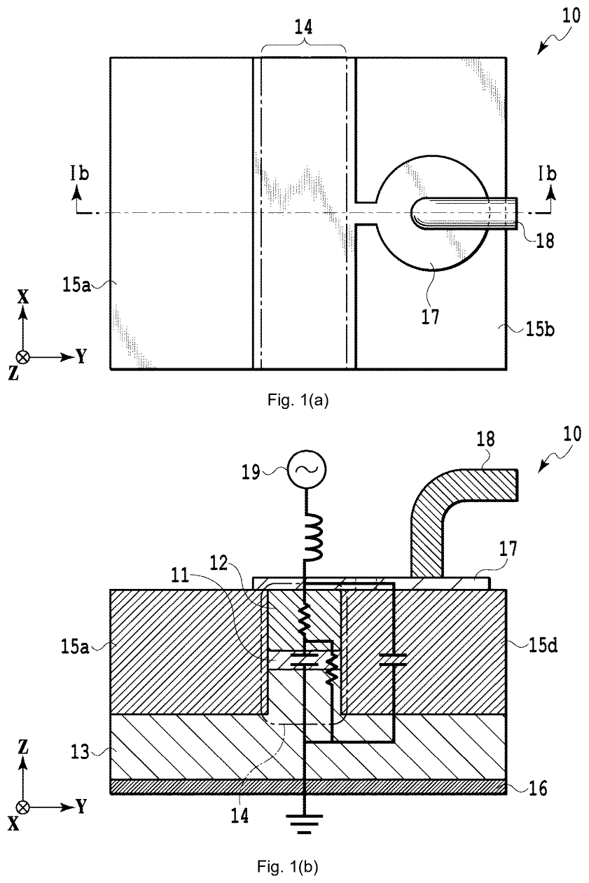

FIG. 2 is a diagram conceptually illustrating a structure of an EA modulator 20 including a low dielectric constant material 21 according to a conventional technology, in which (a) illustrates a top view and (b) illustrates a cross-sectional view taken along a line IIb-IIb.

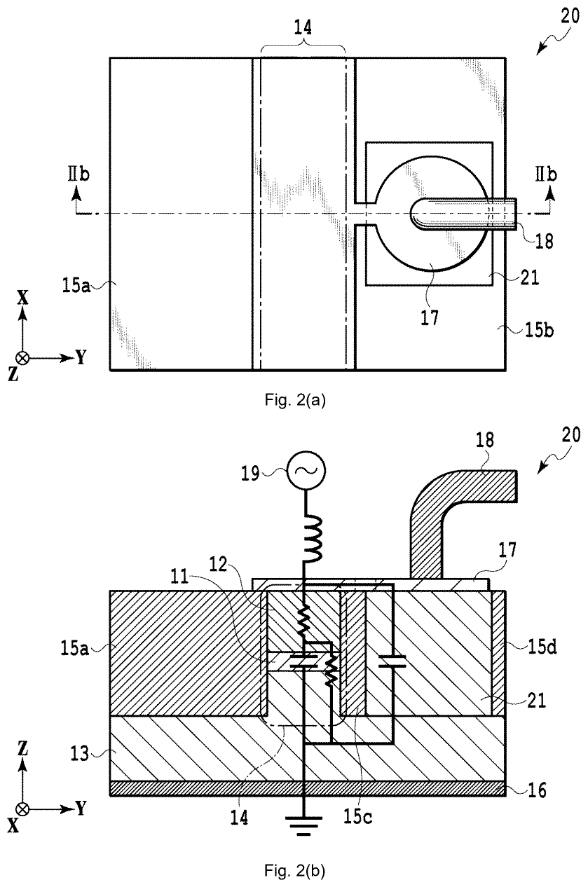

FIG. 3 is a flowchart illustrating a mounting process 30 of an EA modulator including a low dielectric constant material below a signal electrode pad according to the conventional technology.

FIG. 4 is a diagram illustrating, in a pointing manner, implementation in a case where a step in a height direction (z direction) is generated between the low dielectric constant material 21 and an insulating layer 15b and the EA modulator 20 is inclined, in which (a) illustrates an overall view and (b) illustrates an enlarged view of a VI-VI portion.

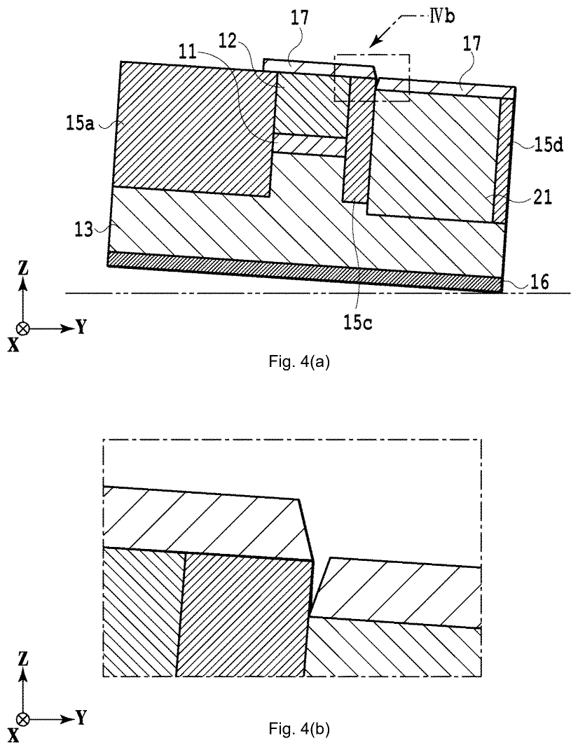

FIG. 5 is a diagram conceptually illustrating a structure of an EA modulator 50 according to a first embodiment of the present disclosure, in which (a) illustrates a top view and (b) illustrates a cross-sectional view taken along a line Vb-Vb.

FIG. 6 is a diagram conceptually illustrating a shape of a mode in which a corner portion of a notch 511 has curvature in the EA modulator 50 according to the first embodiment of the present disclosure.

FIG. 7 is a diagram conceptually illustrating a structure of an EA modulator 70 according to a second embodiment of the present disclosure, in which (a) illustrates a top view and (b) illustrates a cross-sectional view taken along a line VIIb-VIIb.

### DESCRIPTION OF EMBODIMENTS

Hereinafter, various embodiments of the present disclosure will be described in detail with reference to the drawings. The same or similar reference signs denote the same or similar components, and repetitive explanation thereof will be omitted in some cases. The materials and numerical values are for illustrative purposes and are not intended to limit the scope of the disclosure. The following description is an example, and some configurations may be omitted, modified, or implemented together with additional configurations without departing from the gist of an embodiment of the present disclosure.

### First Embodiment

Hereinafter, a first embodiment of the present disclosure will be described in detail with reference to the drawings. An EA modulator in the present embodiment relates to a mode of a structure having a notch in which a low dielectric constant material installed in a lower part of a signal electrode pad is recessed inward.

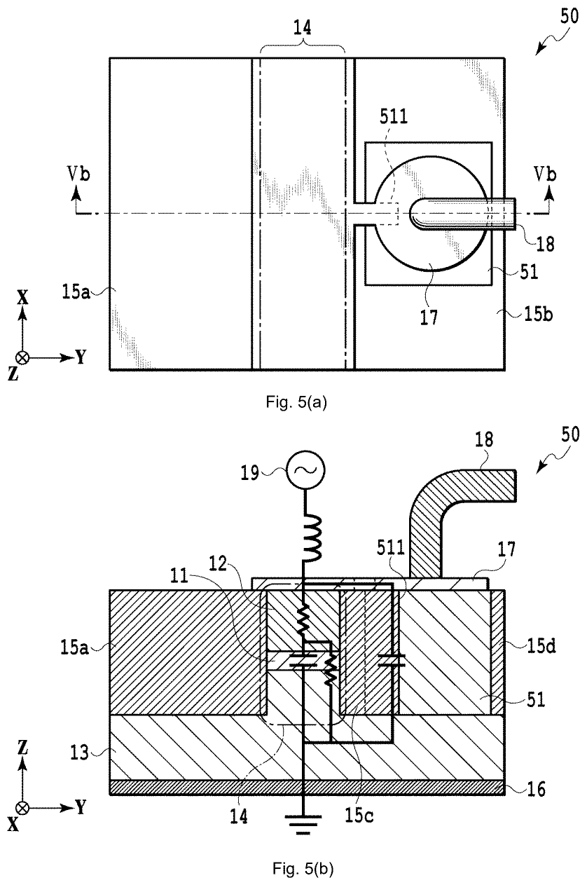

FIG. 5 is a diagram conceptually illustrating a structure of an EA modulator 50 according to the first embodiment of the present disclosure, in which (a) illustrates a top view and (b) illustrates a cross-sectional view taken along a line Vb-Vb. As illustrated in FIG. 5, the EA modulator 50 according to the present embodiment has the same configuration as that of the EA modulator 20 according to the conventional technology, and further includes a cross-piece-shaped notch 511 in which the low dielectric constant material 51 is recessed inward in a direction (y direction) orthogonal to the optical axis direction. In other words, the insulating layer 15 includes the notch 511 in which the insulating layer 15c protruding outward is embedded in the direction (y direction) orthogonal to the optical axis direction. Then, a signal electrode pad 17 is formed on the upper surface of the notch 511 in a z direction.

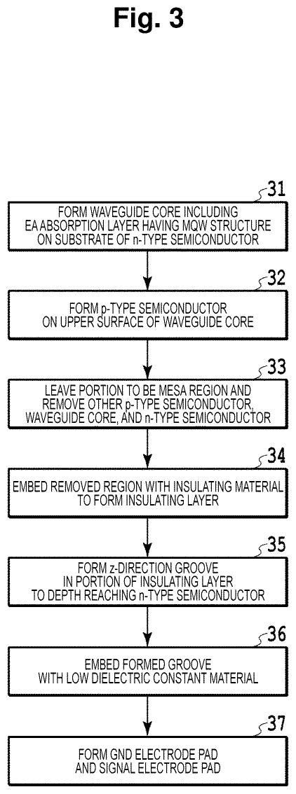

The low dielectric constant material 51 having the notch 511 can be easily achieved by forming a groove having a shape leaving a portion of the notch 511 in advance in step 35 of a mounting process 30 illustrated in FIG. 3. That is, the shape of the low dielectric constant material 51 of the EA modulator 50 is a structure that can be easily achieved by a mounting process according to the conventional technology.

In the EA modulator 50 having such a structure, the low dielectric constant material 51 has a structure having three orthogonal surfaces in the portion of the notch 511. In this case, in the formation of the signal electrode pad 17 by vapor deposition, unless the EA modulator 50 is inclined clockwise with respect to an x axis in FIG. 5(b), at least one surface is always exposed with respect to the flying particles incident from the upper part in the z direction, and a vapor deposition metal is also attached to the surface. As a result, the pad surfaces including steps are connected via vertical surfaces of the steps, so that the occurrence of stepping is suppressed.

In actual, when 20,000 EA modulators 50 were mounted in the mounting process 30, the number of occurrences of stepping was 0. On the other hand, when 20,000 EA modulators 20 according to a conventional technology having the same dimensions were similarly mounted, the number of occurrences of stepping was 450. That is, it has been found that the occurrence rate of the stepping in 20,000 trials is 2.25% in the EA modulator according to the conventional technology, whereas it is 0% in the EA modulator according to the present disclosure. Here, BCB is applied as the low dielectric constant material 51 and the low dielectric constant material 21, and the dimension of the xy plane is 5 μm×25 μm.

From the above, it can be said that the EA modulator (for example, EA modulator 50) according to the present embodiment has been demonstrated to have a structure that achieves a higher yield than the EA modulator (for example, EA modulator 20) according to the conventional technology. By introducing the notch 511, the area of the xy plane of the low dielectric constant material 51 is reduced as compared with the low dielectric constant material 21, and as a result, a decrease in response speed with an increase in capacitance may occur. However, even if the notch 511 is introduced, the reduction ratio of the area is expected to be about 4%, and it is considered that there is almost no contribution to the decrease in the response speed.

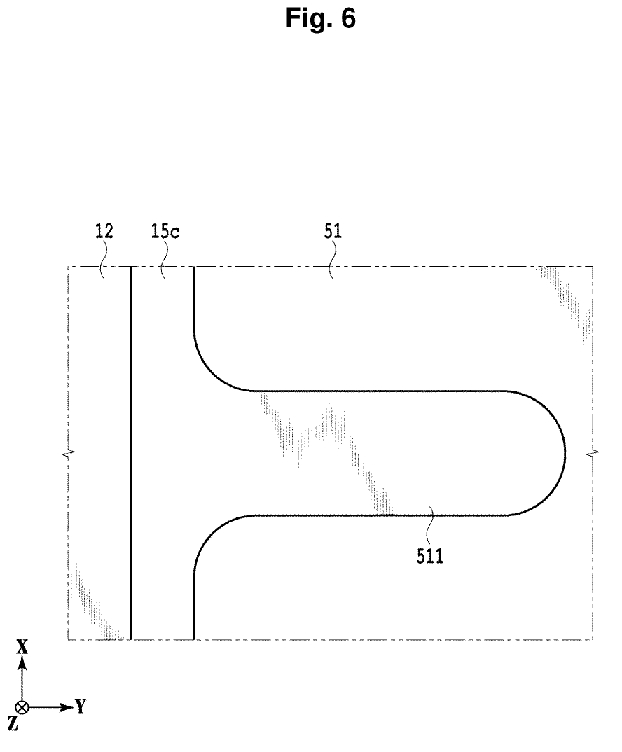

In the present embodiment, the notch 511 of the low dielectric constant material 51 is described as a rectangle in which the corner portion is a right angle, but the present invention is not limited thereto. For example, even a structure in which the corner portion has a curvature as illustrated in FIG. 6 has a similar effect.

The EA modulator 50 according to the present embodiment may be integrated with a DFB laser to constitute an EA-DFB laser. As described above, since the response speed of the EA modulator 50 is equivalent to that of the EA modulator r 20 according to the conventional technology, the EA-DFB laser is an optical transmitter having performance equivalent to that of the conventional technology.

### Second Embodiment

Hereinafter, a second embodiment of the present disclosure will be described in detail with reference to the drawings. An EA modulator in the present embodiment relates to a structure in which a low dielectric constant material installed in a lower part of a signal electrode pad is divided into two.

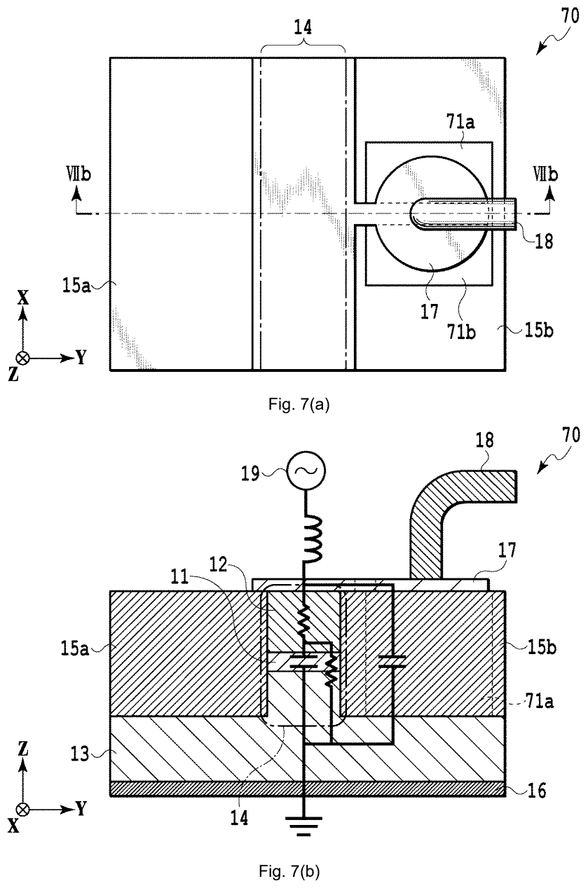

FIG. 7 is a diagram conceptually illustrating a structure of an EA modulator 70 according to the second embodiment of the present disclosure, in which (a) illustrates a top view and (b) illustrates a cross-sectional view taken along a line VIIb-VIIb. As illustrated in FIG. 7, the EA modulator 70 according to the present embodiment has a configuration similar to that of the EA modulator 20 according to the conventional technology, and has a structure in which a low dielectric constant material 61 is divided into two of a first low dielectric constant material 71a and a second low dielectric constant material 71b in a x direction. In other words, the EA modulator 70 has a structure in which the notch 511 in the first embodiment penetrates in a y direction. In other words, the low dielectric constant material 51 in the first embodiment is divided into two in a direction orthogonal to the optical axis direction, and is disposed with a gap corresponding to a notch.

The EA modulator 70 having such a structure has a structure having two parallel surfaces. In addition, since the electrode on the notch 511 is always connected to a mesa region 14 of the EA even in a situation where stepping occurs in the pad, conduction is ensured when a bonding wire 18 is in contact with the notch 511. Therefore, as similar to the first embodiment, it is possible to suppress the occurrence of stepping in the formation of the signal electrode pad 17, and further, it is possible to increase the conduction probability between the GND electrode pad 16 and the signal electrode pad 17.

Since the area of the low dielectric constant material itself is reduced in the EA modulator 70 as compared with the EA modulator 70 described in the first embodiment, the response speed may be reduced. However, on the other hand, since the notch 511 has a structure penetrating in the y direction, the portion does not have a surface parallel to an xz plane. Therefore, it is possible to reliably suppress at least the stepping parallel to the xz plane.

In addition, as similar to the first embodiment, the EA modulator 70 according to the present embodiment may be integrated with a DFB laser to constitute an EA-DFB laser.

### Industrial Applicability

As described above, the EA modulator and the DFB laser according to the present disclosure are expected to be applied as devices for optical transmitters in optical communication since the EA modulator and the DFB laser have a structure capable of suppressing stepping in a mounting process and achieve a high yield.

1. An electro-absorption optical modulator in which a low dielectric constant material is disposed between a signal electrode pad and a GND electrode pad, the low dielectric constant material including a notch recessed inward in a direction orthogonal to an optical axis direction.

2. An electro-absorption optical modulator in which a low dielectric constant material is disposed between a signal electrode pad and a GND electrode pad, the low dielectric constant material being divided into two in a direction orthogonal to an optical axis direction and arranged with a gap.

3. An optical transmitter comprising:
the optical modulator according to claim 1; and
an EA-DFB laser coupled to the optical modulator.

4. An optical transmitter comprising:
the optical modulator according to claim 2; and
an EA-DFB laser coupled to the optical modulator.
